(19) United States
(12) Patent Application Publication
(10) Pub. No.: US 2020/0109481 A1
(43) Pub. Date: Apr. 9, 2020

(54) DISPENSING OF ALKALI METALS VIA ELECTRODEPOSITION USING ALKALI METAL SALTS IN IONIC LIQUIDS

(71) Applicant: HI LLC, Los Angeles, CA (US)

(72) Inventors: Daniel Sobek, Portola Valley, CA (US); Sukanta Bhattacharyya, Belmont, CA (US)

(21) Appl. No.: 16/573,394

(22) Filed: Sep. 17, 2019

Related U.S. Application Data
(60) Provisional application No. 62/798,209, filed on Jan. 29, 2019.
(60) Provisional application No. 62/743,343, filed on Oct. 9, 2018.

(51) Int. Cl. C25D 3/42

(52) U.S. Cl. CPC C25D 3/42; H03L 7/26

(57) ABSTRACT

A method for generating alkali metal in a zero oxidation state includes disposing an alkali metal compound in an ionic liquid, the ionic liquid including an organic cation and an anion; and electrolyzing the alkali metal compound in the ionic liquid to release the alkali metal in the zero oxidation state. The alkali metal in the zero oxidation state can be used in a variety of application including in a vapor cell of a magnetometer.

### CROSS-REFERENCE TO RELATED APPLICATIONS

This application claims the benefit of U.S. Provisional Patent Application Ser. No. 62/743,343, filed Oct. 9, 2018, and 62/798,209, filed Jan. 29, 2019, which are incorporated herein by reference in their entirety.

### FIELD

The present disclosure is directed to the area of dispensing alkali metals. The present disclosure is also directed to the generation of alkali metals in the zero oxidation state, as well as applications that include the dispensed alkali metal.

### BACKGROUND

The manufacture of vapor cells, used in optical magnetometry and atomic clocks, and alkali metal batteries typically includes the dispensing of alkali metals. In at least some of these products, the alkali metal is present in the zero oxidation state. For example, an alkali metal vapor cell can have a vapor of alkali metal atoms in the zero oxidation state. The reactivity of alkali metals to water, oxygen, and other reactants hinders the dispensing of the alkali metals in the zero oxidation state.

A variety of conventional arrangements are used for the dispensing of alkali metals. The following are a few examples. In one conventional method, an alkali dispenser (such as the arrangement commercialized by SAES Getters) is placed inside a double cavity cell. The dispenser is activated after sealing by local laser heating. This reaction creates cesium and non-reactive side reaction products: 2Cs₂CrO₄+ZrAl₂→2Cs+Cr₂O₃+Al2O₃+3ZrO₂. A similar reaction can be used for rubidium. Drawbacks for this arrangement include the SAES pill being relatively large compared to the size of the cell and the zirconium getter nitrogen complicating cell filing. In a paste version, Cs₂CrO₄ is replaced by Cs₂MoO₄. The paste contains a stabilizer and a binder.

Another conventional arrangement uses wax packets. In this method, rubidium is enclosed into wax micropacket produced at wafer scale in a glove box. Vapor cells are then produced with only the desired buffer gas pressure. The cells are sealed at the bottom by only a small SiN layer. The micropacket is then attached to the cells by heating. Finally, a laser removes the SiN layer from the inside of the cell releasing the rubidium inside the cell.

Another conventional arrangement utilizes enriched glass electrolysis. A cesium enriched glass is placed in an electric field inside the cell. This results in the cesium diffusing out of the glass.

### BRIEF SUMMARY

One embodiment is a method for generating alkali metal in a zero oxidation state. The method includes disposing an alkali metal compound in an ionic liquid, the ionic liquid including an organic cation and an anion; and electrolyzing the alkali metal compound in the ionic liquid to release the alkali metal in the zero oxidation state.

In at least some embodiments, electrolyzing the alkali metal compound includes electrodepositing the alkali metal in the zero oxidation state on an electrode. In at least some embodiments, the method further includes transferring the alkali metal in the zero oxidation state from the electrode to a vapor cell. In at least some embodiments, the method further includes evaporating the alkali metal in the zero oxidation state from the electrode.

In at least some embodiments, electrolyzing the alkali metal compound includes electrodepositing the alkali metal in the zero oxidation state on a metallized surface of a vapor cell.

In at least some embodiments, the alkali metal compound is an alkali metal salt. In at least some embodiments, the alkali metal salt is an alkali metal halide, carbonate, sulfide, sulfate, nitrate, or azide.

In at least some embodiments, the organic cation of the ionic liquid includes a heteroatom selected from nitrogen, sulfur, or phosphorus. In at least some embodiments, the organic cation of the ionic liquid is selected from tetraalkylammonium, 1-alkyl-3-methyl imidazolium, 1-alkylpyridinium, N-methyl-N-alkylpyrrolidinium, trialkylsulfonium, or tetraalkylphosphonium. In at least some embodiments, at least alkyl substituent of the organic cation is a C₁ to C₃₀ branched or unbranched alkyl that is optionally substituted with one or more alkenyl, alkynyl, keto, halo, ether, thioether, ester, amino, cycloalkyl, aryl, or heterocyclic substituents.

In at least some embodiments, the anion of the ionic liquid is selected from fluoride, chloride, bromide, tetrafluoroborate, hexafluorophosphate, sulfate, alkylsufonate, or arylsulfonate. In at least some embodiments, the anion of the ionic liquid is selected from trifluoroacetate, triflate, tosylate, formate, alkylsulfate, alkylphosphate, glycolate, or nonafluorobutylsulfonate.

In at least some embodiments, disposing the alkali metal compound in the ionic liquid includes disposing the alkali metal compound in the ionic liquid and an organic solvent. In at least some embodiments, electrolyzing the alkali metal compound includes electrolyzing the alkali metal compound at a temperature of no more than 40° C. In at least some embodiments, electrolyzing the alkali metal compound includes electrolyzing the alkali metal compound at a temperature of no more than 30° C. In at least some embodiments, electrolyzing the alkali metal compound includes electrolyzing the alkali metal compound in a nonaqueous environment. In at least some embodiments, electrolyzing the alkali metal compound includes electrolyzing the alkali metal compound in an inert atmosphere.

Another embodiment is a vapor cell that includes a vessel; and alkali metal disposed in the vessel, wherein the alkali metal is disposed in the vessel by electrolyzing the alkali metal compound in an ionic liquid to release the alkali metal in a zero oxidation state.

In at least some embodiments, the alkali metal in the zero oxidation state is electrodeposited onto a metallized surface of the vessel. In at least some embodiments, the alkali metal in the zero oxidation state is evaporated from a filament into the vessel.

### BRIEF DESCRIPTION OF THE DRAWINGS

Non-limiting and non-exhaustive embodiments of the present invention are described with reference to the following drawings. In the drawings, like reference numerals refer to like parts throughout the various figures unless otherwise specified.

For a better understanding of the present invention, reference will be made to the following Detailed Description, which is to be read in association with the accompanying drawings, wherein:

FIG. 1A is a schematic block diagram of one embodiment of a magnetometer, according to the invention;

FIG. 1B is a schematic block diagram of one embodiment of a magnetic field measurement system, according to the invention;

FIG. 2 is a schematic side view of one embodiment of an array of magnetometers for measuring magnetic fields generated in a brain of a user, according to the invention; and

FIG. 3 is a schematic side view of one embodiment of the array of magnetometers of FIG. 2, a signal source in a brain of a user, and a direction of the ambient background magnetic field.

### DETAILED DESCRIPTION

The present disclosure is directed to the area of dispensing alkali metals. The present disclosure is also directed to the generation of alkali metals in the zero oxidation state, as well as applications that include the dispensed alkali metal.

Conventional methods for generating and dispensing alkali metals in the zero oxidation state may not be suitable or amenable to particular applications. For example, the reaction arrangement may not be suitable for a relatively small vapor cell, the kinetics and equilibrium may not be known, and some of the compounds (e.g., reactants) may be highly toxic.

As described herein, dispensing of alkali metals can be performed on metal surfaces via electrodeposition or electrolysis using alkali metal salt precursors in electrically conducting ionic liquid solvents. In at least some embodiments, this process may occur at ambient or room temperature.

The alkali metal can be electrodeposited on a suitable metal surface that can then be used to provide or dispose the alkali metal in a vapor cell. In some embodiments, the alkali metal can be electrodeposited on, for example, a surface inside a vapor cell that is coated or otherwise metallized. For example, a portion of the surface of the vapor cell can have a thin (for example, 10 to 100 nm or more) layer of conductive material (for example, gold or indium tin oxide or any other suitable metal, alloy, or conductive compound). Other arrangements of a metal component or metal layer in the vapor cell can be used.

Alternatively or additionally, in some embodiments, the alkali metal can be electrodeposited on, for example, a heating filament. This filament may be heated inside a vapor cell (or a connected side chamber in the vapor cell) to evaporate the alkali metal into the vapor cell. Following the evaporation, the filament may be removed from the vapor cell (or from the connected side chamber in the vapor cell.)

Electrolysis techniques often include an inert ionic solvent for dissolution of the electrolyzer for flow of current. Alkali metal salts cannot be electrolyzed in protic solvents, such as water, to generate zero oxidation state alkali metal because this process generates hydrogen at the cathode instead of zero oxidation state alkali metal as alkali metal cations have a much higher reduction potential than proton. A conventional option is to use a mixture of molten inorganic salts, but this requires very high temperature to operate.

Instead, as described herein, the electrodeposition of alkali metals on conductive surfaces can utilize an ionic liquid as an inert, electrically conducting medium. Ionic liquids are also referred to as ionic fluids, liquid electrolytes, liquid salts, liquid organic salts, ambient temperature liquid salts, and room temperature ionic liquids.

Advantages of using an ionic liquid as an electrolyte (instead of mixed inorganic salts that are liquid only at very high temperature) can include one or more of the following: a) ionic liquids can provide a wide electrochemical window to perform electrolysis; b) ionic liquids can remain inert under the conditions of electrolysis; c) non-aqueous conditions provided by ionic liquids allow electrodeposition of zero oxidation state alkali metals; d) ionic liquids can be liquid at room temperature; e) depending on the application, electrochemical and other properties of ionic liquids may be tuned up by systematic structural variation of the cation or anion; or f) ionic liquids can be soluble in aprotic organic solvents such as acetonitrile, tetrahydrofuran, dioxane, or the like, facilitating removal of the excess ionic liquid from the electrodes just by rinsing.

Ionic liquids, as used herein, are a class of compounds composed of 1) one or more organic cations and 2) one or more charge-neutralizing anions which may be organic or inorganic. Preferably, the cations and anions of the ionic liquid retain their ionic properties while in the liquid state. Preferably, the ionic liquid has a melting point, and is a liquid, at or below ambient temperature (e.g., room temperature or 20° C.) or at or below 25, 30, 40, or 50° C. Preferably, the ionic liquid is a liquid in the absence of water. The presence of water can be detrimental to dispensing alkali metals due to the reactivity of alkali metals with water. Preferably, the ionic liquid can be readily separated from water so that the electrodeposition can occur in a water-free or nonaqueous environment (for example, no more than 1, 0.5, or 0.1 wt. % water).

In at least some embodiments, each of the one or more organic cations of the ionic liquid includes one or more heteroatoms such as nitrogen, sulfur, phosphorus, or the like or any combination thereof. In at least some embodiments, the organic cation of the ionic liquid is asymmetric with respect to the heteroatom. In at least some embodiments, the heteroatom may be part of an aryl or non-aryl ring. In at least some embodiments, the organic cation of the ionic liquid can further include one or more organic substituents extending from the heteroatom, where the organic substituents can include one or more C1 to C30 branched or unbranched alkyl substituents which can be unsubstituted or substituted. As an example, the alkyl can be optionally substituted with one or more alkenyl, alkynyl, keto, halo, ether, thioether, ester, amino, cycloalkyl, aryl, or heterocyclic substituents.

Examples of suitable organic cations include, but are not limited to, tetraalkylammonium, 1-alkyl-3-methyl imidazolium, 1-alkylpyridinium, N-methyl-N-alkylpyrrolidinium, trialkylsulfonium, or tetraalkylphosphonium, where each alkyl group is a C₁ to C₃₀ alkyl which can be unsubstituted or substituted. As an example, the alkyl can be optionally substituted with one or more alkenyl, alkynyl, keto, halo, ether, thioether, ester, amino, cycloalkyl, aryl, or heterocyclic substituents.

In at least some embodiments, the choice of cationic and anionic moieties for the ionic liquid can be used to tune the ionic liquid properties related to the electrolysis. In at least some embodiments, selection or modification of the substituents, heteroatom, or other portions of the organic cation can be used to modify one or more properties of the ionic liquid that are relevant to the electrodeposition. Such properties can include, for example, melting point of the ionic liquid, viscosity, solubility of the alkali metal salt, miscibility with organic solvents, a widening of the electrochemical window, or the like.

The one or more anions can be any suitable inorganic or organic anions. Examples of suitable inorganic anions include, but are not limited to, fluoride, chloride, bromide, iodide, tetrafluoroborate, hexafluorophosphate, sulfate, alkylsufonate, arylsulfonate or the like. Examples of suitable organic anions include, but are not limited to, trifluoroacetate, triflate, tosylate, formate, alkylsulfate, alkylphosphate, glycolate, nonafluorobutylsulfonate, or the like.

In at least some embodiments, the ionic liquid possesses a balance of hydrophobic and hydrophilic character to maintain solubility in organic solvents and have the ability to dissolve alkali metal salts. In at least some embodiments, the ionic liquid is miscible or soluble with one or more organic solvents, such as, but not limited to, acetonitrile, tetrahydrofuran, dioxane, dimethylformamide, dimethylacetamide, N-methylpyrrolidone, or the like. In at least some embodiments, the electrodeposition is conducted using a mixture of one or more ionic liquids and one or more organic solvents.

In at least some embodiments, the ionic liquid can dissolve one or more inorganic alkali metal salts, such as alkali metal halides, carbonates, sulfides, sulfates, nitrates, azides, or the like. Alternatively or additionally, one or more organic solvents can be used to dissolve the inorganic alkali metal salts.

Electrodeposition includes the use of an electrochemical cell, in any suitable form, in combination with the ionic liquid, alkali metal salt, and optional organic solvent. The alkali metal salt, such as an alkali metal halide, acts as the electrolyzer and the ionic liquid (with optional organic solvent) is an inert, electrically conducting solvent. The electrochemical cell includes a container, one or more cathodes, and one or more anodes. The cathodes/anodes can be arranged in parallel or in series. Examples of suitable cathode materials include, but are not limited to, tungsten, platinum, nickel, stainless steel, titanium, zirconium, graphite, or mixtures or combinations thereof. The cathode may be of any shape and size. Examples of suitable anode materials include, but are not limited, graphite, titanium, zirconium, nickel, platinum, and iridium, or combinations or mixtures thereof. The cathodes are the electrodes onto which the alkali metal is typically deposited.

For electrodeposition, a voltage or current is applied (for example, a voltage in the range 1.0 to 1.6V or any other suitable voltage) between the cathode and anode. In at least some embodiments, the electrodeposition takes place at or near ambient or room temperature, for example, a temperature in the range of 20 to 40° C. or higher, such as up to 50 to 60° C. or more.

During electrodeposition, the alkali metal ions are reduced (by accepting electrons) at the cathode surface and deposited onto the cathode. The counter-anion (for example, a halide such as chlorine) is oxidized (by releasing an electron) at the anode surface and released (for example, in the case of chlorine, as chlorine gas.)

One embodiment of an electrodeposition reaction scheme is the following

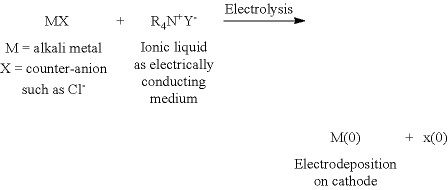

M is an alkali metal selected from lithium, sodium, potassium, rubidium, cesium, or francium;

X is a counter-anion such as, for example, fluorine, chlorine, bromine, or iodine;

R₄N⁺ is the organic cation of the ionic liquid, as described above, and is, in this example, a tetraalkylammonium cation; and

Y⁻ is an inorganic or organic anion of the ionic liquid as described above.

In at least some embodiments, the alkali metal is electrodeposited on a filament (which acts as the cathode). This filament can be placed inside a vapor cell and heated by, for example, DC or AC Joule heating to evaporate the electrodeposited alkali metal into the vapor cell so that the evaporated alkali metal is deposited on the internal surface of the vapor cell. In at least some embodiments, after the evaporation, the filament is removed from the vapor cell, and the vapor cell can be sealed. It will be understood, however, that other methods can be used to transfer or disposed the alkali metal in the vapor cell.

In at least some embodiments, the electrodeposition is performed in an inert gas (for example, argon or nitrogen) environment to avoid exposing the electrodeposited alkali metal to oxygen or water vapor. In at least some embodiments, the evaporation is also performed in an inert gas environment.

In at least some embodiments, dispensing of the alkali metal can be performed in a target vessel, such as a vapor cell, prior to sealing it. In at least some embodiments, dispensing of the alkali metal is compatible with MEMS vapor cell fabrication. In at least some embodiments, the alkali metal may be electrodeposited within a very well defined region (for example, the region of the vapor cell having a conductive metal layer.) In at least some embodiments, all electrodeposition precursors are relatively inexpensive and safe (for example, the precursors do not react violently with water or oxygen). In at least some embodiments, the dispensing method does not use getter gases. In at least some embodiments, the reaction is performed at or near room temperature (for example, no more than 20, 25, 30 or 40° C.) for electrodeposition of zero oxidation state alkali metal.

The alkali metal obtained by electrodeposition can be utilized in a number of different applications. For example, the alkali metal can be dispensed into a vapor cell (or gas cell), as described above. One application of such a vapor cell is in an optically pumped magnetometer.

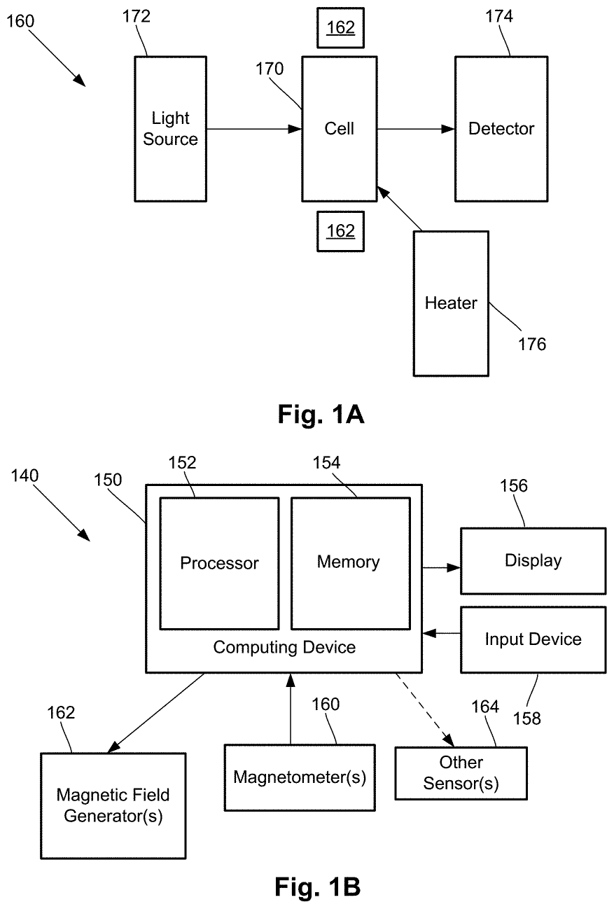

FIG. 1A is a schematic block diagram of one embodiment of a magnetometer 160 which includes a vapor cell 170 (also referred to as a “cell”) such as an alkali metal vapor cell; a heating device 176 to heat the cell 170; a light source 172; and a detector 174. In addition, coils of a magnetic field generator 162 can be positioned around the vapor cell 170. The vapor cell 170 can include, for example, an alkali metal vapor (for example, rubidium in natural abundance, isotopically enriched rubidium, potassium, or cesium, or any other suitable alkali metal such as lithium, sodium, or francium) and, optionally, one, or both, of a quenching gas (for example, nitrogen) and a buffer gas (for example, nitrogen, helium, neon, or argon). In some embodiments, the vapor cell may include the alkali metal atoms in a prevaporized form prior to heating to generate the vapor.

The light source 172 can include, for example, a laser to, respectively, optically pump the alkali metal atoms and probe the gas cell. The light source 172 may also include optics (such as lenses, waveplates, collimators, polarizers, and objects with reflective surfaces) for beam shaping and polarization control and for directing the light from the light source to the cell and detector. Examples of suitable light sources include, but are not limited to, a diode laser (such as a vertical-cavity surface-emitting laser (VCSEL), distributed Bragg reflector laser (DBR), or distributed feedback laser (DFB)), light-emitting diode (LED), lamp, or any other suitable light source. In some embodiments, the light source 172 may include two light sources: a pump light source and a probe light source.

The detector 174 can include, for example, an optical detector to measure the optical properties of the transmitted probe light field amplitude, phase, or polarization, as quantified through optical absorption and dispersion curves, spectrum, or polarization or the like or any combination thereof. Examples of suitable detectors include, but are not limited to, a photodiode, charge coupled device (CCD) array, CMOS array, camera, photodiode array, single photon avalanche diode (SPAD) array, avalanche photodiode (APD) array, or any other suitable optical sensor array that can measure the change in transmitted light at the optical wavelengths of interest.

A magnetometer can be used as part of a magnetic field measurement system. FIG. 1B is a block diagram of components of one embodiment of a magnetic field measurement system 140. The system 140 can include a computing device 150 or any other similar device that includes a processor 152, a memory 154, a display 156, an input device 158, one or more magnetometers 160 (for example, an array of magnetometers) which can be optically pumped magnetometers (OPMs), one or more magnetic field generators 162, and, optionally, one or more other sensors 164 (e.g., non-magnetic field sensors). The system 140 and its use and operation will be described herein with respect to the measurement of neural signals arising from one or more magnetic field sources of interest in the brain of a user as an example. It will be understood, however, that the system can be adapted and used to measure signals from other magnetic field sources of interest including, but not limited to, other neural signals, other biological signals, as well as non-biological signals.

The computing device 150 can be a computer, tablet, mobile device, field programmable gate array (FPGA), microcontroller, or any other suitable device for processing information or instructions. The computing device 150 can be local to the user or can include components that are non-local to the user including one or both of the processor 152 or memory 154 (or portions thereof). For example, in at least some embodiments, the user may operate a terminal that is connected to a non-local computing device. In other embodiments, the memory 154 can be non-local to the user.

The computing device 150 can utilize any suitable processor 152 including one or more hardware processors that may be local to the user or non-local to the user or other components of the computing device. The processor 152 is configured to execute instructions stored in the memory 154.

Any suitable memory 154 can be used for the computing device 150. The memory 154 illustrates a type of computer-readable media, namely computer-readable storage media. Computer-readable storage media may include, but is not limited to, volatile, nonvolatile, non-transitory, removable, and non-removable media implemented in any method or technology for storage of information, such as computer readable instructions, data structures, program modules, or other data. Examples of computer-readable storage media include RAM, ROM, EEPROM, flash memory, or other memory technology, CD-ROM, digital versatile disks (“DVD”) or other optical storage, magnetic cassettes, magnetic tape, magnetic disk storage or other magnetic storage devices, or any other medium which can be used to store the desired information and which can be accessed by a computing device.

Communication methods provide another type of computer readable media; namely communication media. Communication media typically embodies computer-readable instructions, data structures, program modules, or other data in a modulated data signal such as a carrier wave, data signal, or other transport mechanism and include any information delivery media. The terms “modulated data signal,” and “carrier-wave signal” includes a signal that has one or more of its characteristics set or changed in such a manner as to encode information, instructions, data, and the like, in the signal. By way of example, communication media includes wired media such as twisted pair, coaxial cable, fiber optics, wave guides, and other wired media and wireless media such as acoustic, RF, infrared, and other wireless media.

The display 156 can be any suitable display device, such as a monitor, screen, or the like, and can include a printer. In some embodiments, the display is optional. In some embodiments, the display 156 may be integrated into a single unit with the computing device 150, such as a tablet, smart phone, or smart watch. In at least some embodiments, the display is not local to the user. The input device 158 can be, for example, a keyboard, mouse, touch screen, track ball, joystick, voice recognition system, or any combination thereof, or the like. In at least some embodiments, the input device is not local to the user.

The magnetic field generator(s) 162 can be, for example, Helmholtz coils, solenoid coils, planar coils, saddle coils, electromagnets, permanent magnets, or any other suitable arrangement for generating a magnetic field. The optional sensor(s) 164 can include, but are not limited to, one or more position sensors, orientation sensors, accelerometers, image recorders, or the like or any combination thereof.

The one or more magnetometers 160 can be any suitable magnetometer including, but not limited to, any suitable optically pumped magnetometer (e.g., vector magnetometers). Arrays of magnetometers are described in more detail herein. In at least some embodiments, at least one of the one or more magnetometers (or all of the magnetometers) of the system is arranged for operation in a spin exchange relaxation free (SERF) mode.

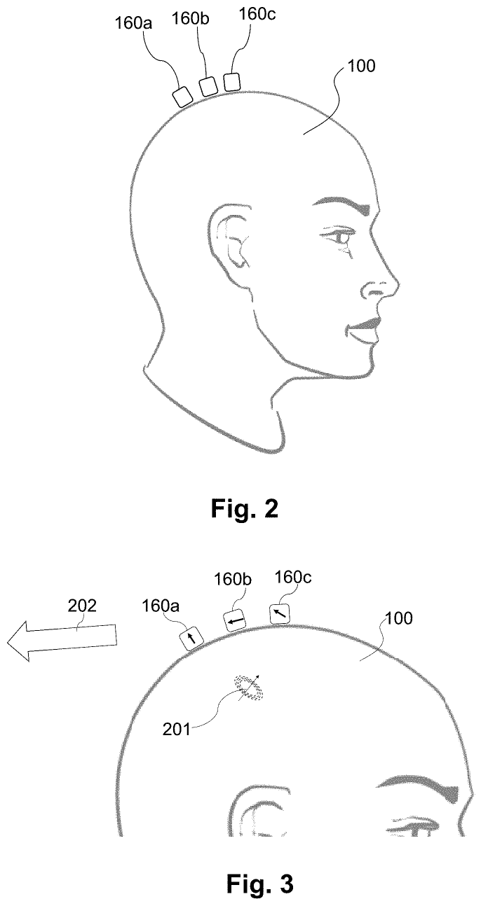

FIG. 2 illustrates one embodiment of a magnetic field measurement system shown with several magnetometers, 160a, 160b, 160c placed on or near a user's head 100 to measure neural activity. FIG. 3 illustrates vector magnetic fields (e.g., signals) that might be generated by the neural activity 201 on each of the magnetometers. For each of the magnetometers 160a, 160b, 106c, the magnetic field vector could be different in both direction and amplitude. The ambient background magnetic field 202 (including, for example, the Earth's magnetic field) is about 10⁸ times larger than magnetic field from the neural activity and is not shown to scale. Examples of magnetic field measurement systems are described in U.S. patent application Ser. Nos. 16/213,980; 16/405,382; 16/418,478; 16/418,500; 16/428,871; 16/456,975; and Ser. No. 16/457,655, and U.S. Provisional Patent Application Ser. Nos. 62/689,696; 62/699,596; 62/719,471; 62/719,475; 62/719,928; 62/723,933; 62/732,327; 62/732,791; 62/741,777; 62/743,343; 62/747,924; 62/745,144; 62/752,067; 62/776,895; 62/781,418; 62/796,958; 62/798,209; 62/798,330; 62/804,539; 62/826,045; 62/827,390; 62/836,421; 62/837,574; 62/837,587; 62/842,818; 62/855,820; 62/858,636; 62/860,001; 62/865,049; 62/873,694; 62/874,887; 62/883,399; 62/883,406; 62/888,858; 62/895,197; and 62/896,929, all of which are incorporated herein by reference in their entireties.

The above specification provides a description of the invention and its manufacture and use. Since many embodiments of the invention can be made without departing from the spirit and scope of the invention, the invention also resides in the claims hereinafter appended.

What is claimed as new and desired to be protected by Letters Patent of the United States is:

1. A method for generating alkali metal in a zero oxidation state, the method comprising
disposing an alkali metal compound in an ionic liquid, the ionic liquid comprising an organic cation and an anion; and
electrolyzing the alkali metal compound in the ionic liquid to release the alkali metal in the zero oxidation state.

2. The method of claim 1, wherein electrolyzing the alkali metal compound comprises electrodepositing the alkali metal in the zero oxidation state on an electrode.

3. The method of claim 2, further comprising transferring the alkali metal in the zero oxidation state from the electrode to a vapor cell.

4. The method of claim 2, further comprising evaporating the alkali metal in the zero oxidation state from the electrode.

5. The method of claim 1, wherein electrolyzing the alkali metal compound comprises electrodepositing the alkali metal in the zero oxidation state on a metallized surface of a vapor cell.

6. The method of claim 1, wherein the alkali metal compound is an alkali metal salt.

7. The method of claim 6, wherein the alkali metal salt is an alkali metal halide, carbonate, sulfide, sulfate, nitrate, or azide.

8. The method of claim 1, wherein the organic cation of the ionic liquid comprises a heteroatom selected from nitrogen, sulfur, or phosphorus.

9. The method of claim 8, wherein the organic cation of the ionic liquid is selected from tetraalkylammonium, 1-alkyl-3-methyl imidazolium, 1-alkylpyridinium, N-methyl-N-alkylpyrrolidinium, trialkylsulfonium, or tetraalkylphosphonium.

10. The method of claim 9, wherein at least alkyl substituent of the organic cation is a C₁ to C₃₀ branched or unbranched alkyl that is optionally substituted with one or more alkenyl, alkynyl, keto, halo, ether, thioether, ester, amino, cycloalkyl, aryl, or heterocyclic substituents.

11. The method of claim 1, wherein the anion of the ionic liquid is selected from fluoride, chloride, bromide, tetrafluoroborate, hexafluorophosphate, sulfate, alkylsufonate, or arylsulfonate.

12. The method of claim 1, wherein the anion of the ionic liquid is selected from trifluoroacetate, triflate, tosylate, formate, alkylsulfate, alkylphosphate, glycolate, or nonafluorobutylsulfonate.

13. The method of claim 1, wherein disposing the alkali metal compound in the ionic liquid comprises disposing the alkali metal compound in the ionic liquid and an organic solvent.

14. The method of claim 1, wherein electrolyzing the alkali metal compound comprises electrolyzing the alkali metal compound at a temperature of no more than 40° C.

15. The method of claim 1, wherein electrolyzing the alkali metal compound comprises electrolyzing the alkali metal compound at a temperature of no more than 30° C.

16. The method of claim 1, wherein electrolyzing the alkali metal compound comprises electrolyzing the alkali metal compound in a nonaqueous environment.

17. The method of claim 1, wherein electrolyzing the alkali metal compound comprises electrolyzing the alkali metal compound in an inert atmosphere.

18. A vapor cell, comprising:
a vessel; and
alkali metal disposed in the vessel, wherein the alkali metal is disposed in the vessel by electrolyzing the alkali metal compound in an ionic liquid to release the alkali metal in a zero oxidation state.

19. The vapor cell of claim 18, wherein the alkali metal in the zero oxidation state is electrodeposited onto a metallized surface of the vessel.

20. The vapor cell of claim 18, wherein the alkali metal in the zero oxidation state is evaporated from a filament into the vessel.
